(19) United States
(12) Patent Application Publication
(10) Pub. No.: US 2012/0205775 A1
(43) Pub. Date: Aug. 16, 2012

(54) METHOD FOR MANUFACTURING AN ELECTRONIC DEVICE

(75) Inventors: Alfred HAEUSLER, Freising (DE); Wolfgang SCHWARTZ, Au (DE)

(73) Assignee: TEXAS INSTRUMENTS INCORPORATED, Dallas, TX (US)

(21) Appl. No.: 13/372,926

(22) Filed: Feb. 14, 2012

(30) Foreign Application Priority Data
Feb. 14, 2011 (DE) 10 2011 011 157.3

(51) Int. Cl. H01L 29/06; H01L 21/762

(52) U.S. Cl. 257/506; 438/424; 257/E21.546; 257/E29.005

(57) ABSTRACT

The invention relates to a method for manufacturing a semiconductor device. Accordingly, the trench processing sequence is changed and stress absorbing layers are applied. A shallow trench structure is etched. A deep trench structure is etched. A liner oxide is applied in the deep and shallow trench structure. An amorphous polysilicon liner is deposited on top of the liner oxide. A nitride liner is applied on top of the amorphous polysilicon liner, and the deep and shallow trenches are filled with oxide.

### FIELD OF THE INVENTION

The invention relates to a method for manufacturing a semiconductor electronic device and an electronic device, and more specifically to a method for manufacturing an electronic device in a silicon on insulator (SOI) technology.

### BACKGROUND

Silicon on insulator technologies widely use shallow and deep trench isolation structures in order to isolate the components from each other. Using shallow and deep trenches have the advantage to provide good isolation breakdown characteristics while being able to remarkably shrink the component size as well as distances from component to component.

FIG. 1 shows a cross section of a typical BICMOS (Bipolar Complementary Metal Oxide Silicon) device in a silicon on insulator technology. On the substrate 1, there is an oxide isolation layer. On top of the oxide isolation layer 2 there is a first CMOS tank 3 and a second CMOS tank 4. The first CMOS tank 3 and the second CMOS tank 4 may have the same basic properties in order to build N-type or P-type MOS transistors. A respective transistor structure 100 is shown for the first CMOS tank 3. It comprises a gate material 5 for forming a gate. There is further the drain region 6, the source region 7 and a gate oxide 8 between the gate material 5 and a channel that will be generated between the drain 6 and the source 7.

Furthermore, there is a shallow trench (STI) 9 and a deep trench (DT) 10 structure for insulating the transistor 100. The shallow trench 9 and the deep trench 10 generally insulate the first CMOS tank 3 from the second CMOS tank 4. The trenches 9, 10 and the oxide layer 2 provide that the first transistor 10 is completely insulated from any other transistor (for example a transistor built in the second CMOS tank 4). FIG. 1 also shows a top view on transistor 100 built on the first CMOS tank 3. The arrow indicates the direction of the cross section shown above the top view. Only very advanced technologies of today include insulation schemes with full oxide insulation in order to get optimum breakdown characteristics. These insulation schemes are supposed to have minimum capacitive parasitic effect. However, the use of full oxide insulation schemes for rather high voltage levels requires that the minimum insulation distances are increased, which entails that the stress related components have to increase, too. This adversely affects the characteristics of the oxide fill material and electrical effects like stored charges in fill oxide become more significant. The negative effects may even eliminate the improvements and there is a risk that next generation technologies may not even provide the required process windows anymore. Since deep and shallow trenches are filled at the same time, it is even more difficult to accommodate the different requirements.

The basic requirements for trench isolation schemes are scalability, isolation properties close to isolation material electrical breakdown limits, stress free isolation in order to avoid interaction of isolation stress and component stress. In particular, the thermal expansion (positive or negative) of a silicon oxide, a silicon substrate or other materials are different. This can result in cracks in thin layers destroying the electrical properties of the components or inhomogeneous electrical properties of matched components. One solution is to fill shallow and deep trench isolation structures layer by layer with oxide, however, it is desirable and cost-effective to fill the shallow and the deep trench with a single oxide since this requires only a single CMP step. In particular, analog components require high precision and good matching which are requirements that suffer from the inhomogeneities or defects introduced during processing.

### SUMMARY

It is an object of the invention to provide an electronic device and a method for manufacturing an electronic device in a silicon on insulator technology. A deep and shallow trench structure may be provided with three layers before a CVD oxide is deposited for filling the shallow and deep trench. The three additional layers are deposited as liners for the deep and shallow trench structure. The three layers comprise a liner oxide, an amorphous poly silicon and a silicon nitride (Si₃N₄). Each layer or liner covers the layer or liner of a previous step entirely. This means that the three liners/layers cover the whole inner surface of the deep and shallow trench structure layer by layer. The combination of these three layers provides several advantages. The liner oxide provides a almost ideal surface termination of the active component tank, which then prevents traps and charges of the fill oxide. The amorphous poly silicon layer operates as a buffer (mechanical stress). The nitride layer improves the electrical breakdown and serves as a blocking layer against unwanted diffusion effects and elements from the non-stoichiometric silicon oxide (SiO₂) fill material. At the same time, the silicon nitride (Si₃N₄) layer compensates at least partially the reduction of insulation due to the amorphous poly silicon layer such that the scalability and the performance of the technology is improved. The three layers (liner oxide, an amorphous poly silicon and a silicon nitride are part of the electronic device and remain within the deep and shallow trench as previously described.

According to an aspect of the invention, in the method for manufacturing a semiconductor device, the trench processing sequence may be changed and stress absorbing layers are applied. A CMOS tank is formed on a silicon substrate in a silicon on insulator technology. A first layer of photo resist is applied on the CMOS tank. A shallow trench isolation structure is etched in accordance with the photo resist pattern. The first layer of photo resist is removed (photo resist strip). A liner oxide is applied (first liner oxidation step). A second layer of photo resist is applied and a deep trench is etched in accordance with the pattern defined by the second layer of photo resist. The second photo resist layer is removed (photo resist strip). Any undesired oxide may then be removed (oxide strip). Another liner oxide may be formed (second liner oxidation step) covering the deep and shallow trench structures and the other areas of the CMOS tank. An amorphous polysilicon layer is then formed covering the shallow and deep trench surface as well as the CMOS tank. A nitride layer is deposited on top of the amorphous polysilicon layer covering the polysilicon layer. Furthermore, a fill oxide is deposited on the deep and shallow trenches. A mechanical polishing (CMP) step may then be performed to receive a smooth surface. A plasma etching step may then be performed in order to remove the nitride layer and the amorphous polysilicon layer in the area where a transistor is to be formed on top of the CMOS tank.

By changing the trench processing sequence and using stress absorbing layers with materials where electrical and mechanical properties are already known, the scalability and at the same time the overall technology performance, in particular for analog applications are substantially improved. Furthermore, the component to component matching characteristics also benefit from the new processing sequence.

Methods according to the prior art typically tend to adjust the fill oxide properties and therefore suffer from limited process windows. Other technologies use specific component layouts in order to get stress relief (corner rounding, champhering of edges etc.). However, these solutions can be disadvantageous in terms of isolation volume and required isolation size or even insufficient.

The solution according to aspects of the present invention compensates the layer sequence isolation stress and provides an active component cover in shallow and deep trench areas. Therefore, oxidation in shallow trench isolation areas during high voltage gate oxidation can be prevented which reduces any additional oxidation stress.

According to an aspect of the invention, the step of plasma etching may be adjusted so as to overetch the fill oxide and remove the amorphous polysilicon layer and nitride layer. This can be used to adjust the position of the nitride/polysilicon termination relative to the moat surface level.

According to another aspect of the invention, a further etching step may then be performed for removing the liner oxide and defining thereby the fill oxide height. The etching step for removing the liner oxide and defining the fill oxide height may advantageously be a wet etching step.

The method according to the invention may advantageously be applied in a BICMOS (Bipolar/Complementary (CMOS)) technology. This may be a high performance analog technology on silicon on insulator substrates. Accordingly, the components in this technology are electrically isolated from each other. Supply voltage levels above 10 V, 20 or 30 V or even of 40V may be used. The aspects of the invention are preferably applied in a BICMOS technology with a deep trench width below 0,35 μm.

The present invention also provides a semiconductor electronic device with a liner of an oxide layer, a liner of a layer of an amorphous poly silicon and in a silicon on insulator (SOI) technology. According to an aspect of the invention, the drain and the source regions of a PMOS or NMOS transistor end at the shallow trench at full depths. This means that the drain and/or source regions (the highly doped N- or P-regions of the transistor run until the liner oxide layer of the shallow trench and a they are not getting thinner or shallower before they reach the liner oxide. This improves the electrical characteristics of the transistors.

The semiconductor electronic device may comprise a shallow trench and deep trench structure. The shallow trench and the deep trench are covered with a liner of silicon oxide, a layer of amorphous polysilicon on top of the oxide, and a layer of nitride on top of the amorphous polysilicon. The amorphous polysilicon may then be covered with a fill oxide.

The advantage of an amorphous silicon layer as liner in shallow trench and deep trench structures is the excellent step coverage and conformance of this process. Even with high aspect ratios, the amorphous silicon can act as a stress absorbing layer. Furthermore, there is a silicon nitride layer directly deposited on top of the amorphous polysilicon layer. This silicon nitride layer provides improved stress absorption and increases the well to well breakdown characteristics. This is due to the fact that stoichiometric nitride has a higher breakdown field than silicon oxide (SiO₂). The amorphous polysilicon layer in combination with the silicon nitride layer compensate the fill oxide shrink stress and improve at the same time the breakdown characteristics. There is no need to change the layout of the components in the silicon on insulator technology.

### BRIEF DESCRIPTION OF DRAWINGS

Further aspects and characteristics of the invention will ensue from the following description of a preferred embodiment of the invention with reference to the accompanying drawings.

FIG. 1 shows a cross section and a top view of a CMOS device according to the prior art;

FIG. 2 shows a cross section and a top view of a semiconductor device according to the invention during a manufacturing step;

FIG. 3 shows a cross section and a top view of a semiconductor device according to the invention during a manufacturing step;

FIG. 4 shows a cross section and a top view of a semiconductor device according to the invention during a manufacturing step;

FIG. 5 shows a cross section and a top view of a semiconductor device according to the invention during a manufacturing step; and

FIG. 6 shows a cross section and a top view of a semiconductor device according to the invention in a final manufacturing step.

### DETAILED DESCRIPTION OF AN EXAMPLE EMBODIMENT

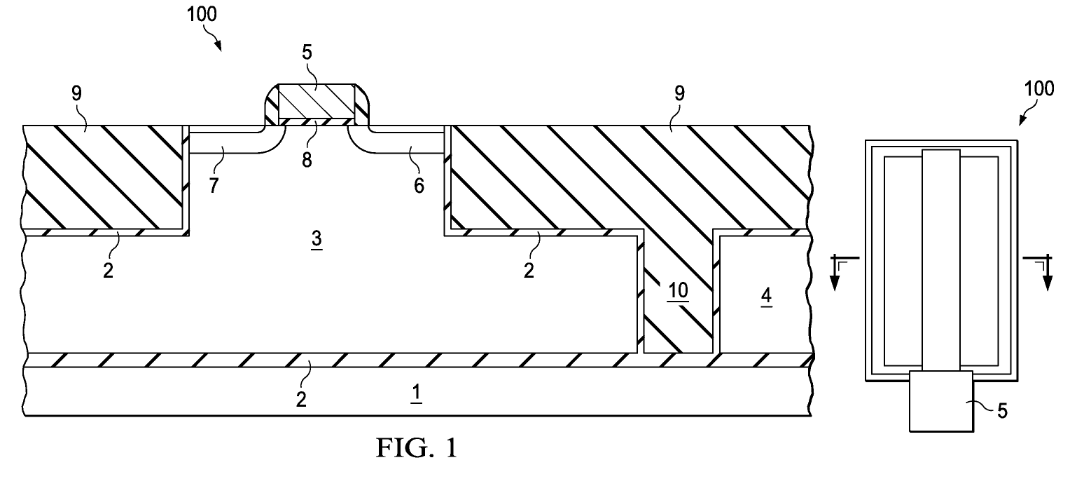

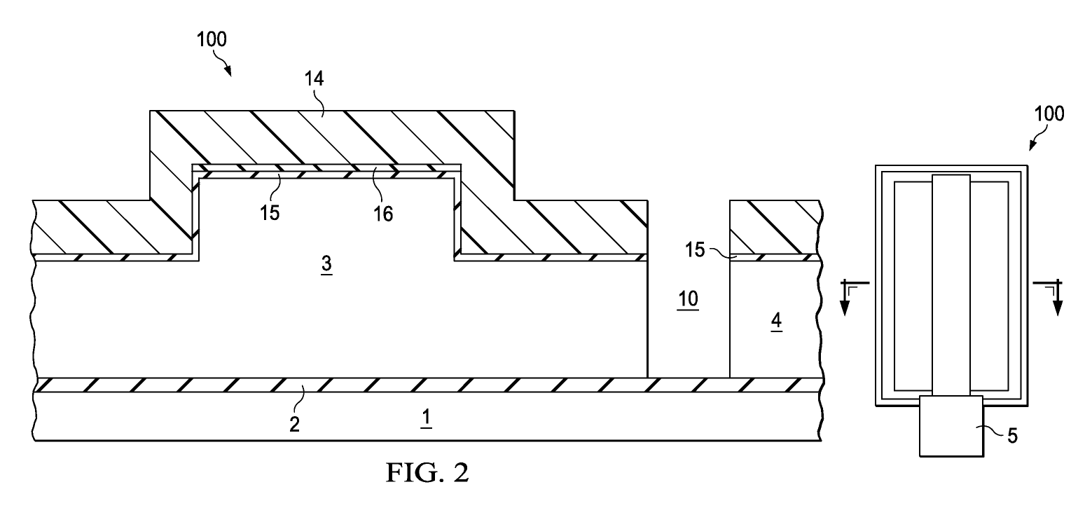

FIG. 2 shows a cross section and a top view of a semiconductor device according to the present invention in a first manufacturing step. There is a silicon on insulator substrate 1, a silicon oxide layer 2 (SiO₂). On top of the silicon oxide layer 2, there is a first CMOS tank 3 and second CMOS tank 4 similar to those shown in FIG. 1. A deep trench 10 and a shallow trench 9 are provided in order to separate and isolate the first CMOS tank 3 from the second CMOS tank 4. A photo resist 14 is deposited on top of an oxide layer 15 covering the first and second CMOS tanks 3 and 4. Furthermore, there is a nitride layer 16 also covering the top of the CMOS tank 3. As known in the art, photo resist is used to cover the structures of the semiconductor device for etching for the shallow trench and the deep trench isolation structures. After etching the shallow trench and removing the resist, the oxidation liner 15 is applied. Then a new layer of photo resist is applied and the deep trench 10 is etched. After each step, the photo resist is removed.

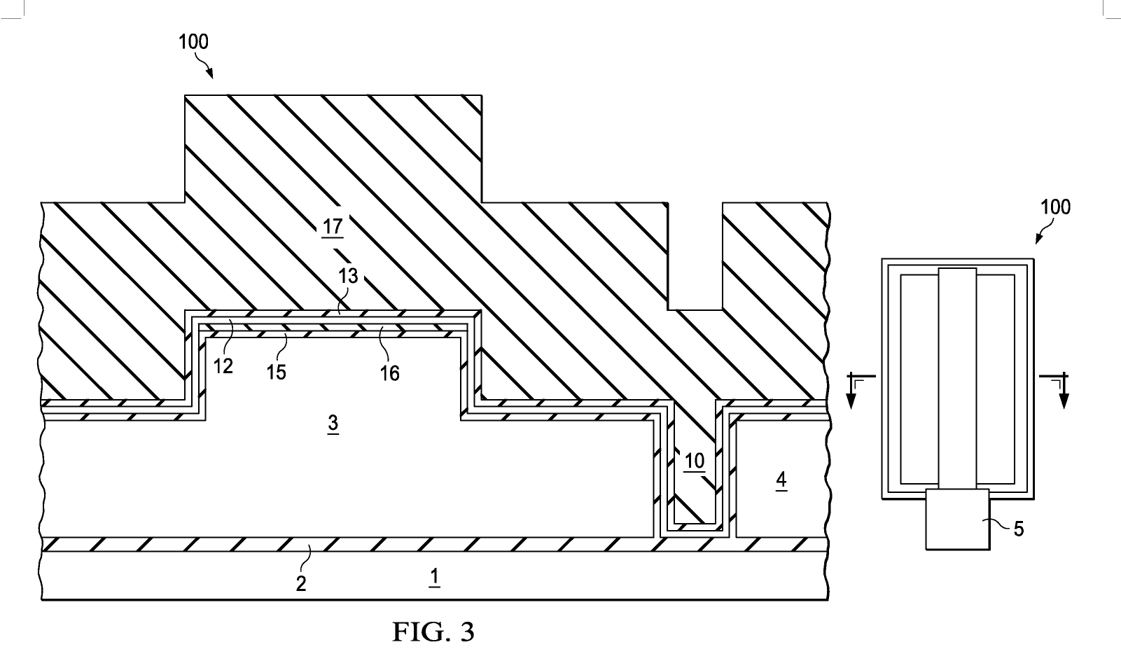

FIG. 3 shows a cross section and a top view of a further manufacturing step of the semiconductor device according to the invention. Accordingly, the photo resist 14 has also been removed and a fill oxide 17 (CVD oxide) is deposited in order to fill the deep trench and shallow trench structures. However, before depositing the fill oxide 17, an amorphous polysilicon layer 12 is deposited in combination with a nitride layer 13. After having removed the photo resist 14 shown in FIG. 2, undesired oxide is removed. A step of liner oxidation is performed in order to provide an oxide liner 15 covering the CMOS tank and the trench structures. In the next step, the amorphous polysilicon layer 12 is deposited. In a further manufacturing step, a silicon nitride layer (Si₃N₄) 13 is deposited on top of the amorphous polysilicon layer 12. Finally, the whole structure is covered with the fill oxide 17.

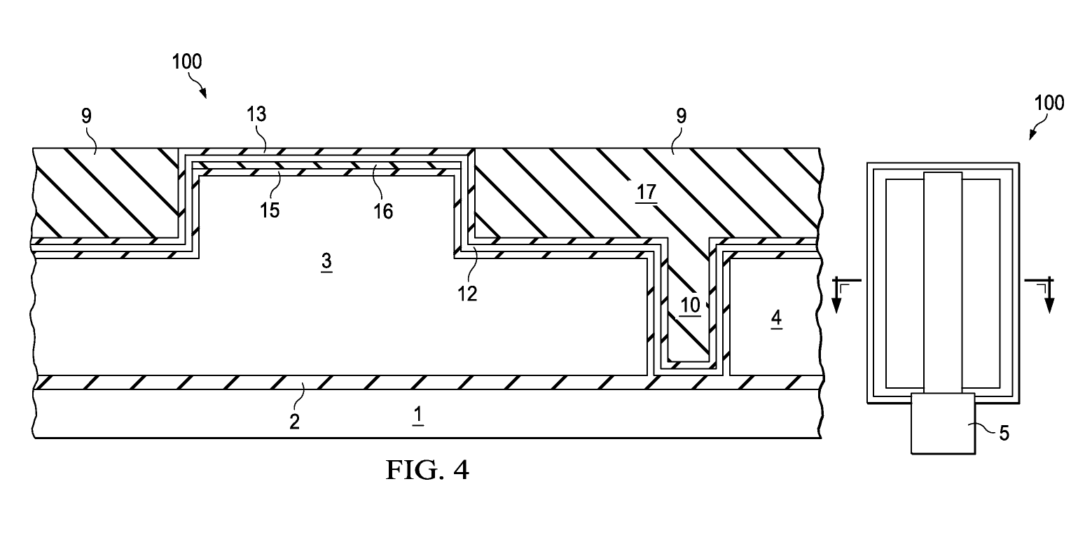

FIG. 4 shows a cross sectional view and a top view of the semiconductor device according to the invention in a further manufacturing step. Accordingly, an inverse moat pattern is applied and a moat etch is performed. This provides that the most elevated parts of the fill oxide 17 shown in FIG. 3 are removed. Finally a chemical-mechanical planarization step (CMP) is performed in order to provide a smooth surface of the semiconductor electronic device. Deep and shallow trench structures are filled at the same time.

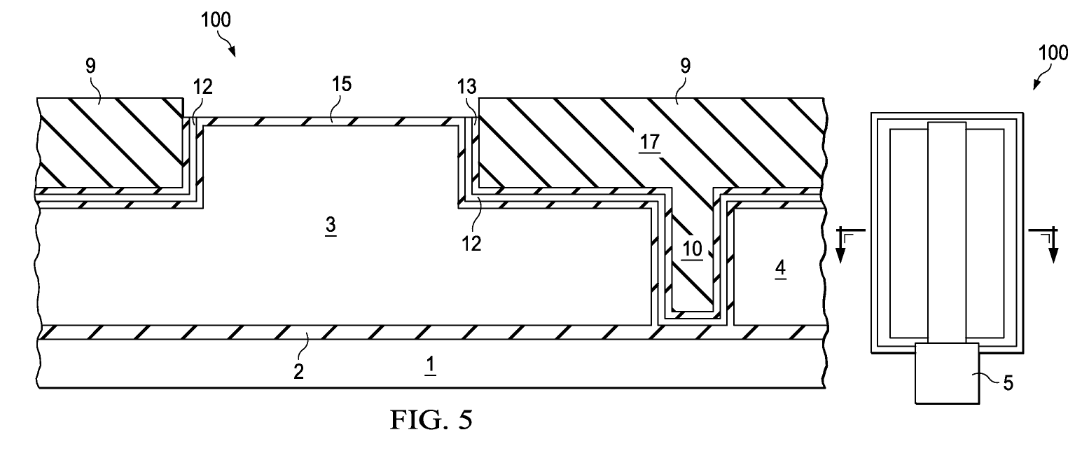

FIG. 5 shows a further manufacturing step of the semiconductor device according to the invention. A plasma etching step is performed in the active area of the first CMOS tank 3 where a transistor 100 is to be formed. With this plasma etching step, the polysilicon layer 12 and the nitride layer 13 are removed from an area, where the active area of the CMOS transistor 100 will be created on top of the first CMOS tank 3. With a further wet etching step, the liner oxide 15 is removed and the depth of the fill oxide 17 is defined.

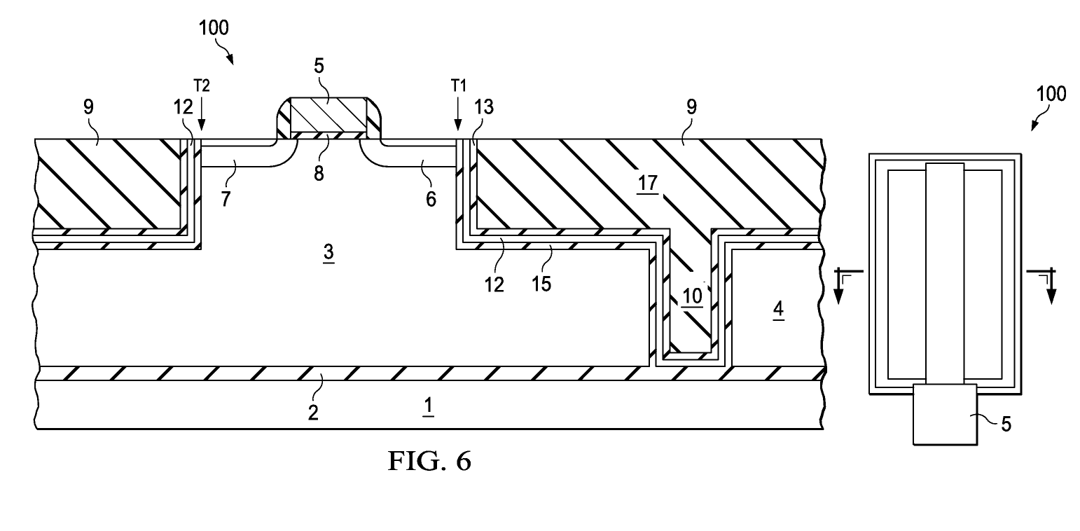

FIG. 6 shows the final state of the manufacturing procedure of the semiconductor electronic device according to the present invention. Accordingly, there is the silicon on insulator substrate 1. The silicon on insulator substrate 1 is covered by a silicon oxide layer 2. A first CMOS tank 3 and a second CMOS tank 4 are built on top of the oxide layer 2. A deep trench 10 and shallow trench 9 structure separate the first CMOS tank 3 from the second CMOS tank 4. The shallow trench 9 and deep trench 10 structures are covered by a liner oxide 15 on top of which an amorphous polysilicon layer 12 and a nitride layer 13 are provided. The shallow trench 9 and deep trench 10 structures are filled with a fill oxide 17. The active area of the first CMOS tank 3 is used for providing a CMOS transistor 100 having drain 6, a source 7, a gate oxide 8 and gate contact 5.

The arrows T1 and T2 indicates the end of the drain and source regions 6,7 of the transistor 100. As can be seen from FIG. 6, these regions run until they reach the liner oxide of the shallow trench in their full depths.

Although the invention has been described hereinabove with reference to a specific embodiment, it is not limited to these embodiment and no doubt further alternatives will occur to the skilled person that lie within the scope of the invention as claimed.

1. A method for manufacturing an electronic device, the method comprising:
etching a shallow trench structure;
etching a deep trench trench structure;
applying a liner oxide in the deep and shallow trench structure;
depositing an amorphous polysilicon liner on top of the liner oxide;
depositing a nitride liner on top of the amorphous polysilicon liner, and
filling the deep and shallow trenches with oxide.

2. The method according to claim 1, further comprising:
forming a CMOS tank on a silicon substrate in a silicon insulated technology;
applying a first layer of photo resist on the CMOS tank;
etching the shallow trench isolation structure;
removing the photo resist;
performing a liner oxidation step;
applying a second layer of photo resist;
etching the deep trench structure;
removing the second photo resist layer;
removing undesired oxide;
applying the liner oxide;
depositing the amorphous polysilicon liner;
depositing the nitride liner;
depositing the fill oxide;
performing a mechanical polishing (CMP) step, and
performing a plasma etching step.

3. The method according to claim 2, wherein the step of plasma etching is configured to overetch in order to adjust a nitride/polysilicon position.

4. The method according to claim 2, wherein a further etching step is performed for removing the liner oxide and defining thereby the fill oxide height.

5. The method according to claim 4, wherein the etching step for removing the liner oxide and defining the fill oxide height is a wet etching step.

6. A semiconductor electronic device in a silicon insulator technology, wherein a shallow trench and deep trench structure comprises a liner of an oxide, a liner of amorphous polysilicon on top of the oxide and a layer of nitride on top of the amorphous polysilicon which is covered by a fill oxide for filling the shallow and deep trench structure.
